(19) United States
(12) Patent Application Publication
(10) Pub. No.: US 2012/0302022 A1
(43) Pub. Date: Nov. 29, 2012

(54) METHOD FOR FORMING AN ASYMMETRIC SEMICONDUCTOR DEVICE

(76) Inventor: Venkat R. Kolagunta, Austin, TX (US)

(21) Appl. No.: 13/117,191

(22) Filed: May 27, 2011

(51) Int. Cl. H01L 21/8234

(52) U.S. Cl. 438/275; 257/E21.619

(57) ABSTRACT

A method for fabricating at least three different types of devices on a semiconductor substrate comprises forming a first electrode region and a second electrode region for a first semiconductor device at the same time as forming a first electrode region of a asymmetrical semiconductor device, and forming a first electrode region and a second electrode region for a second semiconductor device at the same time as forming a second electrode region of the asymmetrical semiconductor device.

### BACKGROUND

1. Field

This disclosure relates generally to semiconductor processing, and more specifically, to a method for forming an asymmetric semiconductor device.

2. Related Art

Different device type have varying requirements due to their characteristics. For example, many analog designs use long gate length devices to minimize random device mismatch. Alternatively, standard Vt devices, such as the core devices, may use a shorter, nominal gate length. Therefore, different designs may require different device types, where for different device types, it may be desirable to use different implant characteristics. However, each additional mask used to form a semiconductor device increases the cost and complexity of the design.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates a cross-sectional view of a semiconductor structure at a first stage in processing, in accordance with one embodiment of the present invention.

FIG. 2 illustrates a cross-sectional view of the semiconductor structure of FIG. 1 at a subsequent stage in processing, in accordance with one embodiment of the present invention.

FIG. 3 illustrates a cross-sectional view of the semiconductor structure of FIG. 2 at a subsequent stage in processing, in accordance with one embodiment of the present invention.

FIG. 4 illustrates a cross-sectional view of the semiconductor structure of FIG. 3 at a subsequent stage in processing, in accordance with one embodiment of the present invention.

FIG. 5 illustrates a cross-sectional view of the semiconductor structure of FIG. 4 at a subsequent stage in processing, in accordance with one embodiment of the present invention.

FIG. 6 illustrates a cross-sectional view of the semiconductor structure of FIG. 5 at a subsequent stage in processing, in accordance with one embodiment of the present invention.

FIG. 7 illustrates a cross-sectional view of the semiconductor structure of FIG. 6 at a subsequent stage in processing, in accordance with one embodiment of the present invention.

FIG. 8 illustrates a top down view of various mask steps used in the formation of the semiconductor structure of FIG. 7, in accordance with one embodiment of the present invention.

### DETAILED DESCRIPTION

In one embodiment, an asymmetric device is formed by using mask steps already in use for the formation of other device types. In this manner, an asymmetric device may be formed without additional mask steps. For example, in one embodiment, a first extension region of an asymmetric device is formed during the formation of extension regions of a first type of device and a second extension region of the same asymmetric device is formed during the formation of extension regions of a second type of device, different from the first type of devices, such that the extension regions of the asymmetric device differ from each other. In this manner, by using mask steps which are used for the formation of other device types, different extension region combinations can be achieved for an asymmetric device.

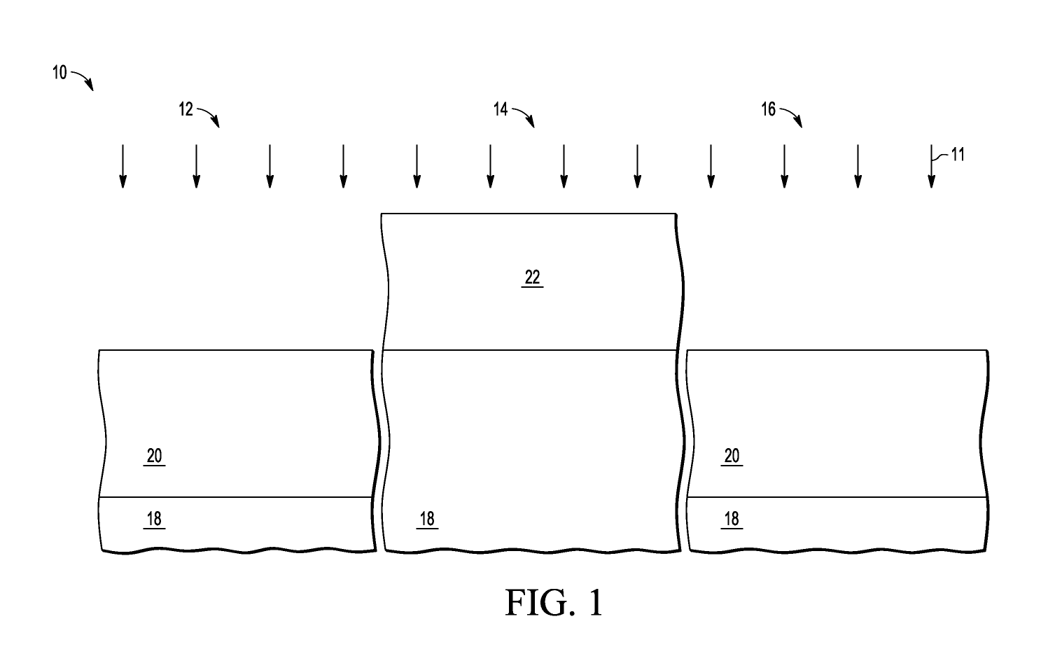

FIG. 1 illustrates, in cross-section form, a semiconductor structure 10 having three different type regions a first stage in processing: a first device region 12 in which a first type of device will be formed, a second device region 14 in which a second type of device will be formed, and an asymmetric device region 16 in which an asymmetric device will be formed. In one embodiment, the first type of device is a standard device and the second type of device is a dual gate oxide (DGO) device. Structure 10 includes a semiconductor substrate 18 which can be any semiconductor material or combinations of materials, such as gallium arsenide, silicon germanium, silicon-on-insulator (SOI), silicon, monocrystalline silicon, the like, and combinations of the above. A patterned masking layer 22 is formed over substrate 18 which exposes regions 12 and 16 while protecting region 14. An implant 11 is performed into substrate 18 in regions 12 and 16 so as to form a well region 20 in each of regions 12 and 16. In one embodiment, such as for the formation of P-type devices, well region 20 is an N-type well. After formation of well regions 20, patterned masking layer 22 may be removed.

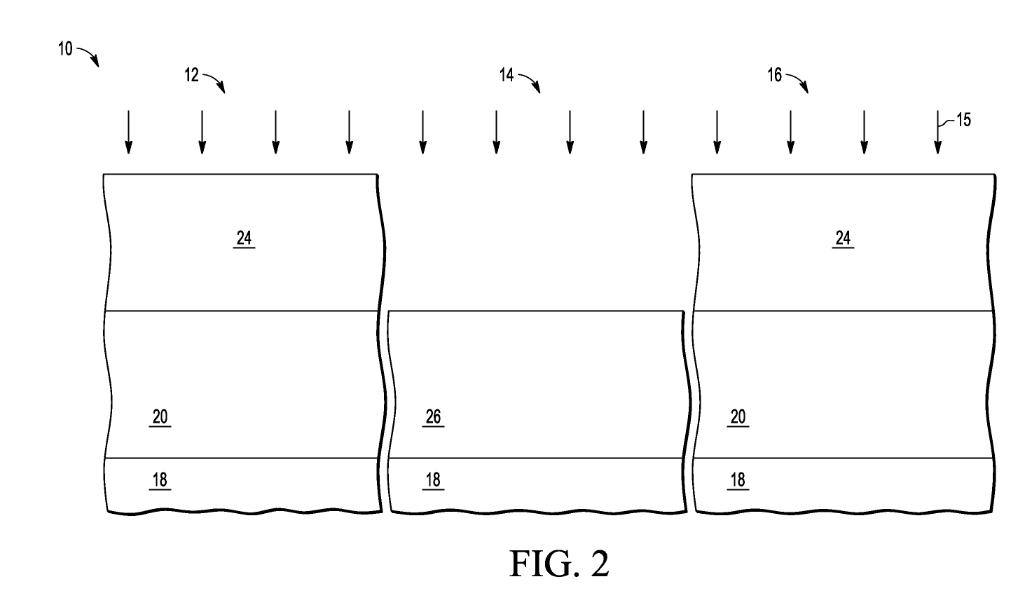

FIG. 2 illustrates, in cross-section form, semiconductor structure 10 after formation of a patterned masking layer 24 which is formed over substrate 10 and exposes region 14 while protecting regions 12 and 16. An implant 15 is performed into substrate 10 in region 14 so as to form a well region 26 in region 14. In the embodiment in which P-type devices are being formed, well region 26 may also be an N-type well; however, it will have different doping characteristics as compared to well region 20 in regions 12 and 16. That is, each of wells 20 and 26 may be different types of wells having the same or different conductivity types. Therefore, note that in the illustrated embodiment, the well region of region 16 is formed using a same mask step as was used to form well region 20 of region 12. That is, a same patterned masking layer (masking layer 22) was used to form both well regions. After formation of well region 26, patterned masking layer 24 may be removed.

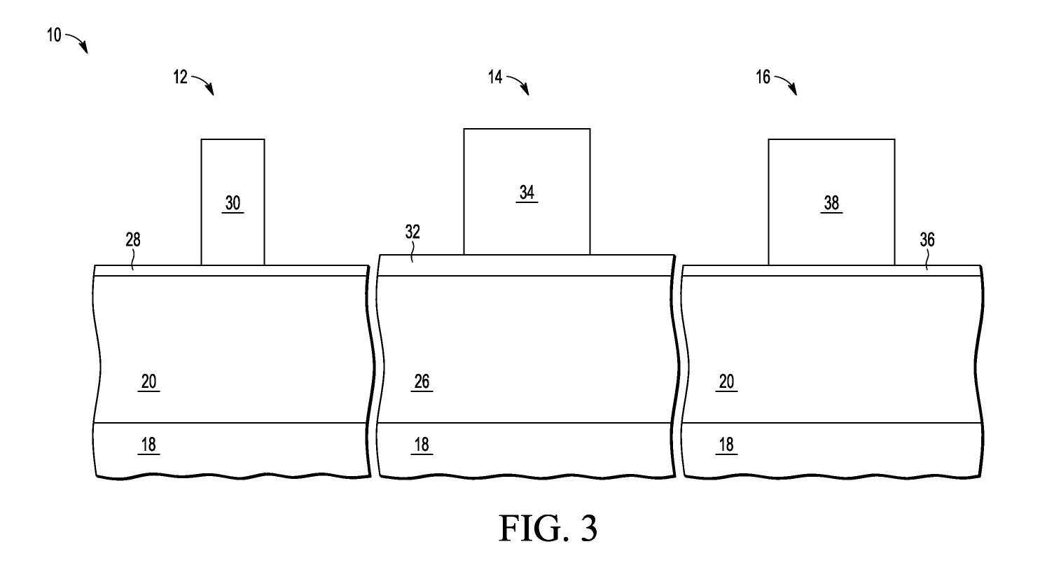

FIG. 3 illustrates, in cross-section form, semiconductor structure 10 after formation of gate oxides and gate electrodes in each of regions 12, 14, and 16. In one embodiment a gate oxide layer 28 is formed over substrate 18 in region 12, a gate oxide layer 32 is formed over substrate 18 in region 14, and a gate oxide layer 36 is formed over substrate 18 in region 16. In one embodiment, the gate oxide in each region is formed in accordance with the type of device to be formed in that region. For example, in the case in which region 14 is a DGO device region, gate oxide layer 32 may be thicker than gate oxide layers 28 and 36 since gate oxide layer 32 is formed for the formation of DGO devices. After formation of the gate oxide layers, a gate electrode may be formed in each region over the corresponding gate oxide layer. A gate electrode 30 is formed over gate oxide layer 28 in region 12, a gate electrode 34 is formed over gate oxide layer 32 in region 14, and a gate electrode 38 is formed over gate oxide layer 36 in region 16. In one embodiment, gate electrodes 30, 34, and 38 are formed from a same layer or plurality of layers. For example, a polysilicon layer may be blanket deposited over the gate oxide layers in regions 12, 14, and 16, and subsequently patterned using a same patterned masking layer to result in each of gate electrodes 30, 34, and 38. Note that each of gate electrodes 30, 34, and 38 may also be referred to as a gate region.

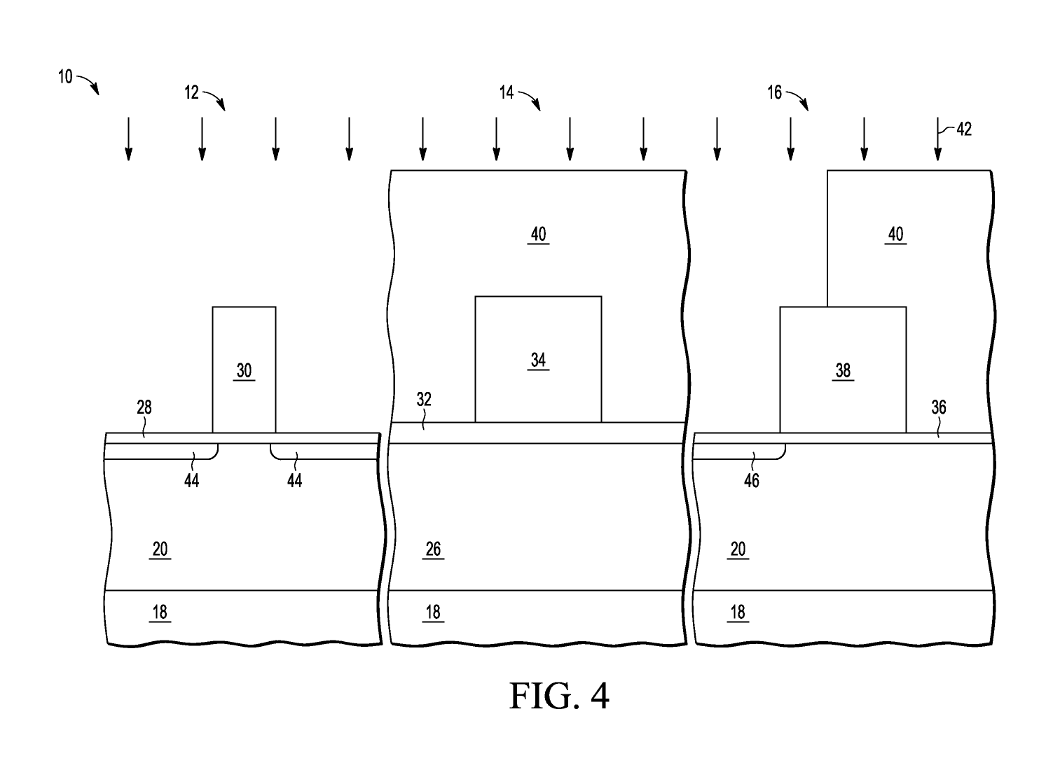

FIG. 4 illustrates, in cross-section form, semiconductor structure 10 after formation of a patterned masking layer 40 which exposes region 12, protects region 14, and partially exposes and partially protects region 16. For example, in region 14, patterned masking layer 40 entirely covers the gate region. However, in region 16, patterned masking layer 40 exposes a first side laterally adjacent to gate electrode 38, but covers and protects a second side, opposite the first side, that is laterally adjacent to gate electrode 38. That is, in region 16, patterned masking layer 40 covers only a first portion of the gate region. An implant 42 is performed into substrate 18 to form extension regions in regions 12 and 16. In region 12, extension regions 44 are formed on each side of gate electrode 30. That is, extension regions 44 are formed on a first side laterally adjacent to gate electrode 30 and on a second side, opposite the first side, that is laterally adjacent to gate electrode 30. However, in region 16, extension regions are formed on only one side of the gate electrode with this mask step and implant. For example, extension region 46 is formed only on the first side that is laterally adjacent to gate electrode 38 (and was exposed by patterned masking layer 40). Note that no extension region is yet formed on the second side of gate electrode 38. Note that extension region 46 will have the same doping characteristics as extension regions 44 since they were formed using the same implant and a same mask step. That is, a same patterned masking layer (e.g. patterned masking layer 40) was used to form extension regions 44 and 46. After formation of extension regions 44 and 46, patterned masking layer 40 may be removed. Note that each of extension regions 44 and 46 may also be referred to as a doped electrode region or an electrode region.

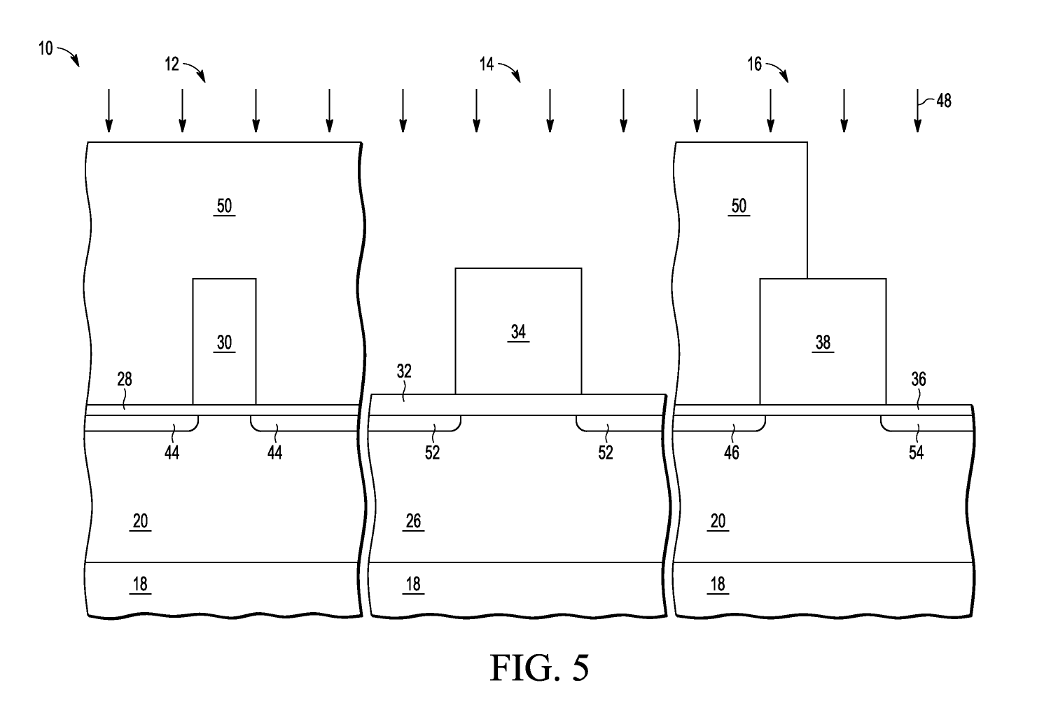

FIG. 5 illustrates, in cross-section form, semiconductor structure 10 after formation of a patterned masking layer 50 which exposes region 14, protects region 12, and partially exposes and partially protects region 16. For example, in region 12, patterned masking layer 50 entirely covers the gate region. However, in region 16, patterned masking layer 50 exposes the second side laterally adjacent to gate electrode 38, but covers and protects the first side (which was previously protected by patterned masking layer 40). That is, in region 16, patterned masking layer 50 covers only a second portion of the gate region. An implant 48 is performed into substrate 18 to form extension regions in regions 14 and 16. In region 14, extension regions 52 are formed on each side of gate electrode 34. That is, extension regions 52 are formed on a first side laterally adjacent to gate electrode 34 and on a second side, opposite the first side, that is laterally adjacent to gate electrode 34. However, in region 16, extension regions are formed on only one side of the gate electrode with this mask step and implant. For example, extension region 54 is formed only on the second side that is laterally adjacent to gate electrode 38 (and was exposed by patterned masking layer 50). Note that extension region 54 will have the same doping characteristics as extension regions 52 since they were formed using the same implant and a same mask step. That is, a same patterned masking layer (e.g. patterned masking layer 50) was used to form extension regions 52 and 54. After formation of extension regions 52 and 54, patterned masking layer 40 may be removed. Note that each of extension regions 52 and 54 may also be referred to as a doped electrode region or an electrode region.

Note that each of implants 42 and 48 described above may include multiple implants having different characteristics, such as different species, conductivities, energies, angles, etc. For example, different implant angles may be used, as needed, to form halo regions during the formation of any of the extension regions. Also, note that each of patterned masking layer 40 and 50, in region 16, have a sidewall which is formed over gate electrode 38 such that only one side (i.e. one sidewall) of gate electrode 38 is exposed. Note that this sidewall for each of patterned masking layer 40 and 50 over gate electrode 38 may be located at different spots over gate electrode 38, so long as only the appropriate side is exposed.

Since different mask steps were used to form extension region 46 and extension region 54 of the same device in region 16, an asymmetric device may be formed in which extension region 46 is not symmetric to extension region 54. For example, they may have different dopant concentrations, different conductivity, different halos, may be formed using different implant energies, or any combination thereof. Also, each of extension regions 46 and 54 may be either P-type regions or N-type regions. Furthermore, note that formation of each of the asymmetric extension region (extension regions 46 and 54), do not require additional mask steps. For example, extension region 46 may be formed simultaneously with the formation of extension regions for a first type of device (such as, for example, during formation of the type of devices in region 12), and extension region 54 may be formed simultaneously with the formation of extension regions for a second type of device (such as, for example, during formation of the type of devices in region 14).

Note that region 12 can be used to form any type of device and region 14 can be used to form any type of device which may be different from those of region 12. For example, they may differ in their well implants, gate dielectrics (e.g. gate oxides), gate electrodes, gate lengths, operating voltages etc., or combinations thereof. Furthermore, the asymmetric devices of region 16 may be any type of devices whose well implants, gate dielectrics (e.g. gate oxides), gate electrodes, and operating voltages are designed as needed for their particular application. For example, the gate dielectric (e.g. gate oxide) of the asymmetric devices of region 16 may be thicker than the gate dielectrics (e.g. gate oxides) of those devices in regions 12 and 14. Also, some characteristics of the asymmetric devices may be the same as those device in region 12 while other characteristics of the asymmetric devices may be the same as those in device region 14. For example, in one embodiment the gate oxide for the device in region 16 is the same as those for region 14. In another embodiment, the type of device in region 12 and the type of device in region 14 operate at different voltages, and an asymmetrical device of region 16 operates at a voltage that is the same as the operating voltage of either the type of device in region 12 or the type of device of region 14. Also, a gate length of an asymmetrical device in region 16 may be greater than a minimum gate length specified for type of device in region 12 or the type of device in region 14. For example, in one embodiment in which region 14 is a DGO device region and region 12 is a standard device region (i.e. a logic device region), the asymmetric devices in region 16 may be analog devices which have long gate lengths similar to those of the DGO devices, but be formed in a same type of well as formed in region 12. In one embodiment, the gate length of the DGO devices and the asymmetric devices are 2 or 3 times longer than the minimum gate length specified for the standard device (i.e. logic devices). Therefore, note that by using the same mask steps used in forming two other types of devices, a third type of device may be formed without additional mask steps.

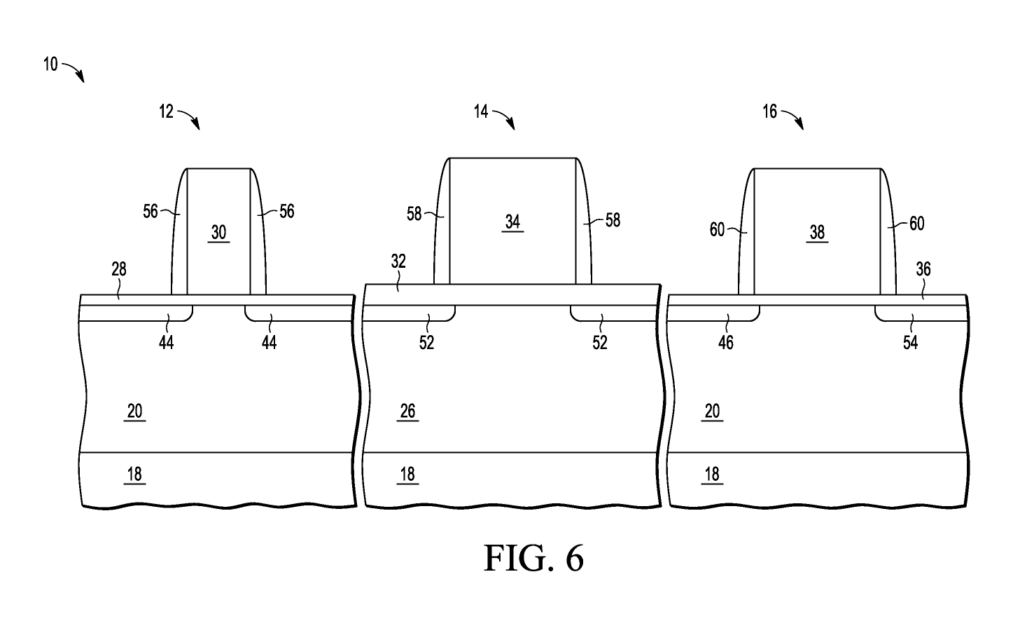

FIG. 6 illustrates, in cross-section form, semiconductor structure 10 after formation of spacers 56, 58, and 60 around gate electrodes 30, 34, and 38 in regions 12, 14, and 16, respectively. Spacer 56 is formed adjacent sidewalls of gate electrode 30, spacer 58 is formed adjacent sidewalls of gate electrode 34, and spacer 60 is formed adjacent sidewalls of gate electrode 38. In one embodiment, the spacers are formed by deposition of an insulating layer over semiconductor substrate 18 in regions 12, 14, and 16, followed by an anisotropic etch.

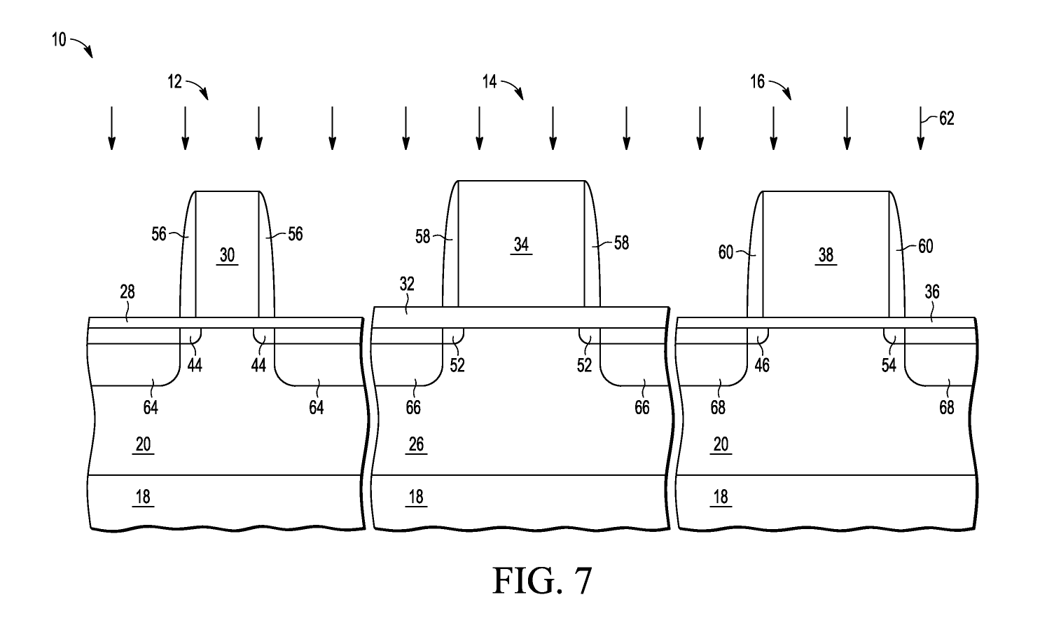

FIG. 7 illustrates, in cross-section form, semiconductor structure 10 after formation of deep source/drain regions in regions 12, 14, and 16. In one embodiment, an implant 62 is performed into substrate 18 to form deep source/drain regions 64 adjacent both the first and second sides of gate electrode 30, deep source/drain regions 66 adjacent both the first and second sides of gate electrode 34, and deep source/drain regions 60 adjacent both the first and second sides of gate electrode 38. In the illustrated embodiment, deep source/drain regions 64, 66, and 68 are simultaneously formed with implant 62. Note that each of deep source/drain regions 64, 66, and 68 may also be referred to as a deep implant region. Processing may then continue as needed to complete semiconductor device structure 10.

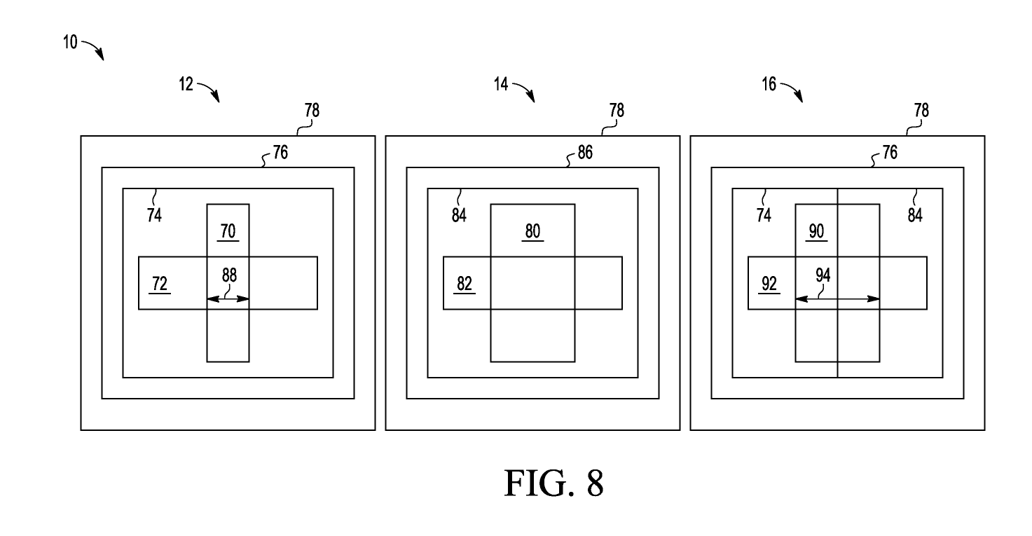

FIG. 8 illustrates a top-down view of the various mask steps used within regions 12, 14, and 16 of semiconductor structure 10. Each of regions 12, 14, and 16 includes a device depicted by the intersection of a polysilicon region (such as regions 70, 80, and 90, respectively) and an active region (such as regions 72, 82, and 92). Regions 70, 80, and 90 may correspond to each of gate electrodes 30, 34, and 38, respectively. Note that, in the illustrated embodiment, gate length 88 in region 12 is shorter than gate length 94 in region 16. In one embodiment, gate length 94 is 2 to 3 times greater than gate length 88. In each of regions 12 and 16, a first outline 76 which surrounds the device is illustrated which corresponds to a first mask step used to form the well regions of regions 12 and 16 (e.g. well regions 20). In region 14, a second outline 86 which surrounds the device corresponds to a second mask step used to form the well region of region 14. A third outline 74 which completely surrounds the device in region 12 and covers only a portion (e.g. the left-hand portion, when looking at the page) of the device in region 16 such that it does not include the other portion (e.g. the right-hand portion) of the device corresponds to a third mask step used to form the extension regions on both sides of the devices in region 12 and to form extension regions on only a first side of devices in region 16. A fourth outline 84 which completely surrounds the device in region 14 and covers only a portion (e.g. the right-hand portion, when looking at the page) of the device in region 16 such that it does not include the other portion (e.g. the left-hand portion) of the device corresponds to a fourth mask step used to form the extension regions on both sides of the devices in region 14 and to form extension regions on only a second side of devices in region 16. Note that, in region 16, the boundaries of outlines 74 and 84 may overlap each other over gate electrode 90 so long as the appropriate sidewall of gate electrode 90 remains exposed. A fifth outline 78 which surrounds each device in each region corresponds to a fifth mask step used to form the deep source/drain regions in each of regions 12, 14, and 16. Therefore, note that the mask steps used in the formation of the device in region 16 each correspond to masking steps already present in the formation of devices in regions 12 and 14. That is, additional mask steps are not needed to form an asymmetric device such as the device of region 16.

Therefore, by now it has been appreciated that by using the same mask steps already present in the formation of other types of devices, an asymmetric device may be formed without the need for additional mask steps. In one embodiment, the extension regions of an asymmetric device differ. For example, an asymmetric device used for long gate length analog devices may help improve mismatch, on resistance and frequency. Therefore, different extension and halo combinations from different types of devices may be used to form asymmetric devices without additional mask steps.

Although the invention has been described with respect to specific conductivity types or polarity of potentials, skilled artisans appreciated that conductivity types and polarities of potentials may be reversed.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. For example the mask steps for use in forming an asymmetric device can be taken from those used in the formation of any other type of device. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

The following are various embodiments of the present invention.

Item 1 includes a method for fabricating an asymmetrical semiconductor device including: on a semiconductor substrate including at least three different regions for different types of devices: forming a first masking layer covering an entire gate region of a first type of semiconductor device and only a first portion of a gate region of the asymmetrical semiconductor device; implanting first and second doped electrode regions of a second type of semiconductor device and a first doped electrode region of the asymmetrical semiconductor device; removing the first masking layer; forming a second masking layer covering an entire gate region of the second type of semiconductor device and only a second portion of a gate region of the asymmetrical semiconductor device; and implanting first and second doped electrode regions of the first type of semiconductor device and a second doped electrode region of the asymmetrical semiconductor device. Item 2 includes the method of item 1, wherein the first doped electrode region of the asymmetrical semiconductor device has a different conductivity than the second doped electrode region of the asymmetrical semiconductor device. Item 3 includes the method of item 1, wherein length of the gate region of the asymmetrical semiconductor device is longer than length of the gate region of one the group consisting of: the first type of semiconductor device and the second type of semiconductor device. Item 4 includes the method of item 1 and further includes forming a first type of well in the second semiconductor device and the asymmetrical semiconductor device; and forming a second type of well in the first semiconductor device. Item 5 includes the method of item 1, wherein the first type of semiconductor device and the second type of semiconductor device operate at different voltages. Item 6 includes the method of item 1, wherein the asymmetrical semiconductor device operates at a voltage that is the same as one of the group consisting of: the first type of semiconductor device and the second type of semiconductor device. Item 7 includes the method of item 1 wherein the asymmetrical semiconductor device operates at a voltage that is different from the first type of semiconductor device and the second type of semiconductor device.

Item 8 includes a method for fabricating at least three different types of devices on a semiconductor substrate including: using a first masking layer covering a gate region of a first type of semiconductor device and only a first portion of a gate region of an asymmetrical semiconductor device to form first and second electrode regions of a second type of semiconductor device and a first electrode region of the asymmetrical semiconductor device; and using a second masking layer covering a gate region of the second type of semiconductor device and only a second portion of a gate region of the asymmetrical semiconductor device to form first and second electrode regions of the first type of semiconductor device and a second electrode region of the asymmetrical semiconductor device, wherein at least a portion of the first and second electrode regions of the asymmetrical semiconductor device have different conductivity. Item 9 includes the method of item 8, wherein the first and second electrode regions of the second type of semiconductor device and the first electrode region of the asymmetrical semiconductor device are one of the group consisting of: P-type regions and N-type regions. Item 10 includes the method of item 8 wherein length of the gate region of the asymmetrical semiconductor device is different than at least one the group consisting of: length of gate region of the first type of semiconductor device and length of gate region of the second type of semiconductor device. Item 11 includes the method of item 8 wherein the first and second electrode regions of the first type of semiconductor device and the second doped electrode region of the asymmetrical semiconductor device are different than the first and second electrode regions of the second type of semiconductor device and the first doped electrode region of the asymmetrical semiconductor device. Item 12 includes the method of item 8 and further includes forming spacers around the gate regions; and forming deep implant regions under only a portion of the first and second electrode regions of the first type of semiconductor device, the first and second electrode regions of the second type of semiconductor device, and the first and second electrode regions of the asymmetrical semiconductor device. Item 13 includes the method of item 8 and further includes forming a first type of well in the second semiconductor device and the asymmetrical semiconductor device; and forming a second type of well in the first semiconductor device. Item 14 includes the method of item 8 wherein the first and second electrode regions of the second semiconductor device and the first electrode region of the asymmetrical semiconductor device have at least one of the group consisting of: different dopant concentrations, different species, different halos, different angled implants, and different implant energies than the first and second electrode regions of the first semiconductor device and the second electrode region of the asymmetrical semiconductor device.

Item 15 includes a method for fabricating at least three different types of devices on a semiconductor substrate including: forming a first electrode region and a second electrode region for a first semiconductor device at the same time as forming a first electrode region of a asymmetrical semiconductor device; and forming a first electrode region and a second electrode region for a second semiconductor device at the same time as forming a second electrode region of the asymmetrical semiconductor device. Item 16 includes the method of item 15 wherein the first and second electrode regions of the second type of semiconductor device and the first electrode region of the asymmetrical semiconductor device are at least one of the group consisting of: P-type regions and N-type regions. Item 17 includes the method of item 15 wherein length of the gate region of the asymmetrical semiconductor device is greater than a minimum gate length specified for at least one the group consisting of: the first type of semiconductor device and the second type of semiconductor device. Item 18 includes the method of item 15 wherein a gate dielectric of the asymmetrical semiconductor device is thicker than gate dielectrics of the first and second semiconductor devices. Item 19 includes the method of item 15 and further includes forming spacers around the gate regions; and forming deep implant regions under only a portion of the first and second electrode regions of the first type of semiconductor device, the first and second electrode regions of the second type of semiconductor device, and the first and second electrode regions of the asymmetrical semiconductor device. Item 20 includes the method of item 15, wherein at least a portion of the first and second electrode regions of the asymmetrical semiconductor device have different conductivity.

What is claimed is:

1. A method for fabricating an asymmetrical semiconductor device comprising:
on a semiconductor substrate including at least three different regions for different types of devices:
forming a first masking layer covering an entire gate region of a first type of semiconductor device and only a first portion of a gate region of the asymmetrical semiconductor device;
implanting first and second doped electrode regions of a second type of semiconductor device and a first doped electrode region of the asymmetrical semiconductor device;
removing the first masking layer;
forming a second masking layer covering an entire gate region of the second type of semiconductor device and only a second portion of a gate region of the asymmetrical semiconductor device; and
implanting first and second doped electrode regions of the first type of semiconductor device and a second doped electrode region of the asymmetrical semiconductor device.

2. The method of claim 1 wherein:
the first doped electrode region of the asymmetrical semiconductor device has a different conductivity than the second doped electrode region of the asymmetrical semiconductor device.

3. The method of claim 1 wherein:
length of the gate region of the asymmetrical semiconductor device is longer than length of the gate region of one the group consisting of: the first type of semiconductor device and the second type of semiconductor device.

4. The method of claim 1 further comprising:
forming a first type of well in the second semiconductor device and the asymmetrical semiconductor device; and
forming a second type of well in the first semiconductor device.

5. The method of claim 1 wherein:
the first type of semiconductor device and the second type of semiconductor device operate at different voltages.

6. The method of claim 1 wherein:
the asymmetrical semiconductor device operates at a voltage that is the same as one of the group consisting of: the first type of semiconductor device and the second type of semiconductor device.

7. The method of claim 1 wherein:
the asymmetrical semiconductor device operates at a voltage that is different from the first type of semiconductor device and the second type of semiconductor device.

8. A method for fabricating at least three different types of devices on a semiconductor substrate comprising:
using a first masking layer covering a gate region of a first type of semiconductor device and only a first portion of a gate region of an asymmetrical semiconductor device to form first and second electrode regions of a second type of semiconductor device and a first electrode region of the asymmetrical semiconductor device; and
using a second masking layer covering a gate region of the second type of semiconductor device and only a second portion of a gate region of the asymmetrical semiconductor device to form first and second electrode regions of the first type of semiconductor device and a second electrode region of the asymmetrical semiconductor device,
wherein at least a portion of the first and second electrode regions of the asymmetrical semiconductor device have different conductivity.

9. The method of claim 8 wherein:
the first and second electrode regions of the second type of semiconductor device and the first electrode region of the asymmetrical semiconductor device are one of the group consisting of: P-type regions and N-type regions.

10. The method of claim 8 wherein:
length of the gate region of the asymmetrical semiconductor device is different than at least one the group consisting of: length of gate region of the first type of semiconductor device and length of gate region of the second type of semiconductor device.

11. The method of claim 8 wherein:
the first and second electrode regions of the first type of semiconductor device and the second doped electrode region of the asymmetrical semiconductor device are different than the first and second electrode regions of the second type of semiconductor device and the first doped electrode region of the asymmetrical semiconductor device.

12. The method of claim 8 further comprising:
forming spacers around the gate regions; and
forming deep implant regions under only a portion of the first and second electrode regions of the first type of semiconductor device, the first and second electrode regions of the second type of semiconductor device, and the first and second electrode regions of the asymmetrical semiconductor device.

13. The method of claim 8 further comprising:
forming a first type of well in the second semiconductor device and the asymmetrical semiconductor device; and
forming a second type of well in the first semiconductor device.

14. The method of claim 8 wherein:
the first and second electrode regions of the second semiconductor device and the first electrode region of the asymmetrical semiconductor device have at least one of the group consisting of: different dopant concentrations, different species, different halos, different angled implants, and different implant energies than the first and second electrode regions of the first semiconductor device and the second electrode region of the asymmetrical semiconductor device.

15. A method for fabricating at least three different types of devices on a semiconductor substrate comprising:
forming a first electrode region and a second electrode region for a first semiconductor device at the same time as forming a first electrode region of a asymmetrical semiconductor device; and
forming a first electrode region and a second electrode region for a second semiconductor device at the same time as forming a second electrode region of the asymmetrical semiconductor device.

16. The method of claim 15 wherein:
the first and second electrode regions of the second type of semiconductor device and the first electrode region of the asymmetrical semiconductor device are at least one of the group consisting of: P-type regions and N-type regions.

17. The method of claim 15 wherein:
length of the gate region of the asymmetrical semiconductor device is greater than a minimum gate length specified for at least one the group consisting of: the first type of semiconductor device and the second type of semiconductor device.

18. The method of claim 15 wherein a gate dielectric of the asymmetrical semiconductor device is thicker than gate dielectrics of the first and second semiconductor devices.

19. The method of claim 15 further comprising:
forming spacers around the gate regions; and
forming deep implant regions under only a portion of the first and second electrode regions of the first type of semiconductor device, the first and second electrode regions of the second type of semiconductor device, and the first and second electrode regions of the asymmetrical semiconductor device.

20. The method of claim 15 wherein:
at least a portion of the first and second electrode regions of the asymmetrical semiconductor device have different conductivity.
